(19) United States
(12) Patent Application Publication
(10) Pub. No.: US 2023/0099463 A1
(43) Pub. Date: Mar. 30, 2023

(54) Window, Door, and Opening Detection for 3D Floor Plans

(71) Applicant: Apple Inc., Cupertino, CA (US)

(72) Inventors: Hongyu Xu, San Jose, CA (US); Feng Tang, Cupertino, CA (US); Kai Kang, Sunnyvale, CA (US)

(21) Appl. No.: 17/945,216

(22) Filed: Sep. 15, 2022

Related U.S. Application Data
(60) Provisional application No. 63/247,834, filed on Sep. 24, 2021.

(51) Int. Cl. G06F 30/13

(52) U.S. Cl. CPC G06F 30/13

(57) ABSTRACT

Various implementations provide a 3D floor plan based on scanning a room and detecting windows, doors, and openings using 2D orthographic projection. Points of a dense set of points (e.g., a dense point cloud) that are close to a plane representing a wall are projected onto the plane and used to identify windows, doors, and opening on the wall. Representations of the detected windows, doors, and openings may then be positioned in a 3D floor plan based on the known position of the wall within the corresponding room, i.e., the location of the wall plane relative to the dense point cloud is known. Other aspects of a 3D floor plan may be detected directly from points of a dense 3D point cloud, windows, doors, and openings may be detected indirectly using projections of the points of the 3D point cloud onto a 2D plane, and the detected aspects may be combined into a single 3D floor plan.

### CROSS-REFERENCE TO RELATED APPLICATIONS

This Application claims the benefit of U.S. Provisional Application Ser. No. 63/247,834 filed Sep. 24, 2021 which is incorporated herein in its entirety.

### TECHNICAL FIELD

The present disclosure generally relates to electronic devices that use sensors to scan physical environments to generate three dimensional (3D) models such as 3D floor plans.

### BACKGROUND

Existing scanning systems and techniques may be improved with respect to assessing and using the sensor data obtained during scanning processes to generate 3D representations such as 3D floor plans representing physical environments.

### SUMMARY

Various implementations disclosed herein include devices, systems, and methods that provide a 3D floor plan based on scanning a room and detecting windows, doors, and openings using 2D orthographic projection. A 3D floor plan is a 3D representation of a room or other physical environment that generally identifies or otherwise represents 3D positions of one or more walls, floors, ceilings, or other boundaries or regions of the environment. Some implementations disclosed herein generate a 3D floor plan that identifies or otherwise represents 3D positions of windows, doors, and/or openings within the 3D floor plan, e.g., on the walls, floors, ceilings, or other regions.

The 3D positions and/or other characteristics of windows, doors, and openings may be determined using 2D orthographic projection. In some implementations, a set of points, such as points of a 3D point cloud, nodes of a 3D mesh, or points of any other 3D representation, is generated to represent a room or other physical environment. The points that are close to a plane representing a wall are projected onto the plane and used to identify windows, doors, and openings on the wall. Representations of the detected windows, doors, and openings may then be positioned in a 3D floor plan based on the known position of the wall within the room, i.e., the location of the wall plane relative to the set of points is known. In some implementations, boundaries or regions corresponding to walls, floors, ceilings, etc., are detected directly from points of the set of points, windows, doors, and openings are detected indirectly using projections of the points of the set of points onto a 2D plane, and these detected aspects are combined into a single 3D floor plan. Detecting the windows, doors, and openings using a 2D projection as opposed to detecting them directly using the points of the set of points may be more accurate, more efficient, or otherwise advantageous.

In some implementations, a processor performs a method by executing instructions stored on a computer readable medium. The method identifies a set of points of a set of points (e.g., a 3D point cloud) representing a physical environment, where the set of points correspond to a wall in the physical environment. In some implementations, the set of points is identified by identifying points that are within a threshold distance of a wall plane prediction. The wall plane prediction may predict the position of a wall surface and approximate positions of wall boundaries and/or openings within the wall surface. The method projects the set of points onto a 2D plane corresponding to the wall, where each point of the set of points is projected to a location on the 2D plane. In some implementations, the set of points is projected via orthographic projection. The projected points may additionally be associated with semantics, color/RGB info, and/or normalized distance information that corresponds to distances of the points from the wall in the 3D point cloud. In some implementations, projecting the points may include producing one or more 2D data sets, for example, including a semantic map, an RGB map, and/or a point distance map (of normalized distance information). The method detects one or more windows, one or more doors, and/or one or more openings based on the set of points projected onto the 2D plane. The detecting may involve predicting parameters that parametrically define the windows, doors, and/or openings in terms of 2D location coordinates, 2D dimensions, and/or other characteristics such as open, closed, percentage open, etc. The method generates a 3D floor plan based on the detecting of a window, door, or opening. Other portions of the 3D floor plan, such as a representation of the wall (and other walls), floors, ceiling, counters, appliances, etc., may be generated based on the 3D point cloud and the windows, doors, and/or openings may be positioned based on a known spatial relationship of the wall plane relative to the set of points. For example, the 3D location of the plane corresponding to the wall within the set of points (e.g., relative to a 3D point cloud) may enable the wall and the windows, doors, and openings detected on it to be positioned relative to a 3D floor plan generated based on the set of points.

In accordance with some implementations, a device includes one or more processors, a non-transitory memory, and one or more programs; the one or more programs are stored in the non-transitory memory and configured to be executed by the one or more processors and the one or more programs include instructions for performing or causing performance of any of the methods described herein. In accordance with some implementations, a non-transitory computer readable storage medium has stored therein instructions, which, when executed by one or more processors of a device, cause the device to perform or cause performance of any of the methods described herein. In accordance with some implementations, a device includes: one or more processors, a non-transitory memory, and means for performing or causing performance of any of the methods described herein.

### BRIEF DESCRIPTION OF THE DRAWINGS

So that the present disclosure can be understood by those of ordinary skill in the art, a more detailed description may be had by reference to aspects of some illustrative implementations, some of which are shown in the accompanying drawings.

FIG. 1 illustrates an exemplary electronic device operating in a physical environment in accordance with some implementations.

FIG. 2 illustrates a 3D point cloud representing the physical environment of FIG. 1 in accordance with some implementations.

FIG. 3 illustrates a wall detected in the 3D point cloud of FIG. 2 in accordance with some implementations.

FIG. 4 illustrates a selection of a subset of the 3D point cloud of FIG. 2 within a threshold distance of the wall of FIG. 3 in accordance with some implementations.

FIG. 5 illustrates a 2D projection of the selected 3D point cloud points of FIG. 4 in accordance with some implementations.

FIG. 6 illustrates an identification of a window and a door in the 2D projection of FIG. 5 in accordance with some implementations.

FIG. 7A illustrates inclusion of the identified window and door of FIG. 6 in a 3D floor plan representing the physical environment of FIG. 1 in accordance with some implementations.

FIGS. 7B and 7C are perspective views of the 3D floor plan of FIG. 7A.

FIG. 8 is a flowchart illustrating inputs and outputs in a process for generating a 3D floor plan in accordance with some implementations.

FIG. 9 is a flowchart illustrating a method for generating a 3D floor plan in accordance with some implementations.

FIG. 10 is a block diagram of an electronic device of in accordance with some implementations.

In accordance with common practice the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DESCRIPTION

Numerous details are described in order to provide a thorough understanding of the example implementations shown in the drawings. However, the drawings merely show some example aspects of the present disclosure and are therefore not to be considered limiting. Those of ordinary skill in the art will appreciate that other effective aspects and/or variants do not include all of the specific details described herein. Moreover, well-known systems, methods, components, devices and circuits have not been described in exhaustive detail so as not to obscure more pertinent aspects of the example implementations described herein.

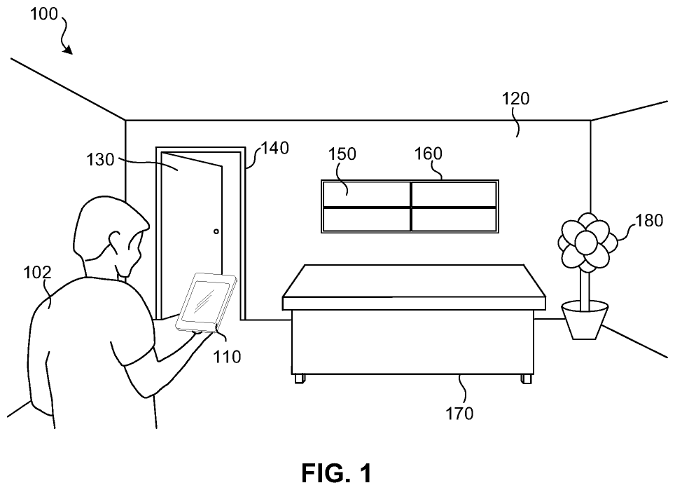

FIG. 1 illustrates an exemplary electronic device 110 operating in a physical environment 100. In this example of FIG. 1, the physical environment 100 is a room that includes a door 130, door frame 140, a window 150, and a window frame 160 on wall 120. The physical environment also includes a desk 170 and potted plant 180. The electronic device 110 includes one or more cameras, microphones, depth sensors, motion sensors, or other sensors that can be used to capture information about and evaluate the physical environment 100. The obtained sensor data may be used to generate a 3D representation, such as a 3D point cloud, a 3D mesh, or a 3D floor plan.

In one example, the user 102 moves around the physical environment 100 and device 110 captures sensor data from which a 3D floor plan of the physical environment 100 is generated. The device 110 may be moved to capture sensor data from different viewpoints, e.g., at various distances, viewing angles, heights, etc. The device 110 may provide information to the user 102 that facilitates the environment scanning process. For example, the device 110 may provide a view from a camera showing the content of RGB images currently being captured, e.g., a live camera feed, during the room scanning process. As another example, the device 110 may provide a view of a live 3D point cloud or a live 3D floor plan to facilitate the scanning process or otherwise provides feedback that informs the user 102 of which portions of the physical environment 100 have already been captured in sensor data and which portions of the physical environment 100 require more sensor data in order to be represented accurately in a 3D representation and/or 3D floor plan.

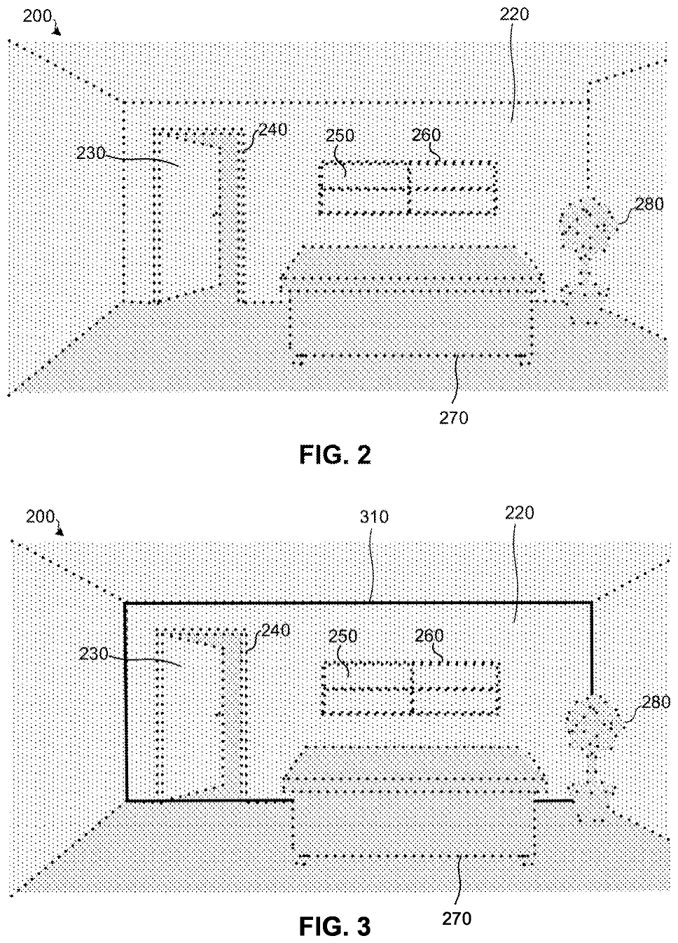

FIGS. 2-7 illustrate aspects of a process in which a 3D floor plan of the physical environment 100 is generated, including representations of the wall 120, the door 130, and the window 150. In this process, a dense point-based representation, such as a 3D point cloud, is generated to represent the physical environment 100. The process is illustrated using a single wall of a multi-wall physical environment 100. However, the generated 3D floor plan may include representations of multiple (e.g., some or all) walls of the 3D environment, for example, by repeating the door/window processes illustrated for one wall in FIGS. 2-7 with respect to the other walls of the physical environment 100.

Accordingly, FIG. 2 illustrates a 3D point cloud that represents the physical environment 100 of FIG. 1. In some implementations, the 3D point cloud 200 is generated based on one or more images (e.g., greyscale, RGB, etc.), one or more depth images, and motion data regarding movement of the device in between different image captures. In some implementations, an initial 3D point cloud is generated based on sensor data and then the initial 3D point cloud is densified via an algorithm, machine learning model, or other process that adds additional points to the 3D point cloud. The 3D point cloud 200 may include information identifying 3D coordinates of points in a 3D coordinate system. Each of the points may be associated with characteristic information, e.g., identifying a color of the point based on the color of the corresponding portion of an object or surface in the physical environment 100, a surface normal direction based on the surface normal direction of the corresponding portion of the object or surface in the physical environment 100, a semantic label identifying the type of object with which the point is associated, etc.

In alternative implementations, a 3D mesh is generated in which points of the 3D mesh have 3D coordinates such that groups of the mesh points identify surface portions, e.g., triangles, corresponding to surfaces of the physical environment 100. Such points and/or associated shapes (e.g., triangles) may be associated with color, surface normal directions, and/or semantic labels.

In the example of FIG. 2, the 3D point cloud 200 includes a set of points 220 representing wall 120, a set of points 230 representing door 130, a set of points 240 representing door frame 140, a set of points 250 representing the window 150, a set of points 260 representing the window frame 160, a set of points 270 representing the desk 170, and a set of points 280 representing the potted plant 180. In this example, the points of the 3D point cloud 200 are depicted with relative uniformity and with points on object edges emphasized to facilitate easier understanding of the figures. However, it should be understood that the 3D point cloud 200 need not include uniformly distributed points and need not include points representing object edges that are emphasized or otherwise different than other points of the 3D point cloud 200.

In the process illustrated in FIGS. 2-7, one or more boundaries and/or regions (e.g., walls, floors, ceilings, etc.) are identified within the physical environment 100. The relative positions of these surfaces may be determined relative to the physical environment 100 and/or the 3D point-based representation 200. Accordingly, FIG. 3 illustrates a wall surface, i.e., wall plane 310, detected with respect to the 3D point cloud 200 of FIG. 2. Various techniques may be used to detect planar regions, such as a wall, floor, ceiling, and the like, and their boundaries. In some implementations, a plane detection algorithm, machine learning model, or other technique is performed using sensor data and/or a 3D point-based representation (such as 3D point cloud 200). The plane detection algorithm may detect the 3D positions in a 3D coordinate system of one or more planes of physical environment 100. The detected planes may be defined by one or more boundaries, corners, or other 3D spatial parameters. The detected planes may be associated with one or more types of features, e.g., wall, ceiling, floor, table-top, counter-top, cabinet front, etc., and/or may be semantically labelled. Detected planes associated with certain features (e.g., walls, ceilings, etc.) may be analyzed with respect to whether such planes include windows, doors, and openings, as explained below.

In FIG. 3, a wall plane 310 is detected and corresponds to wall 120 of the physical environment 100. The 3D position of the wall plane 310 is determined and used to position identify the position of the wall plane 310 with respect to the points of the 3D point cloud 200 of FIG. 2.

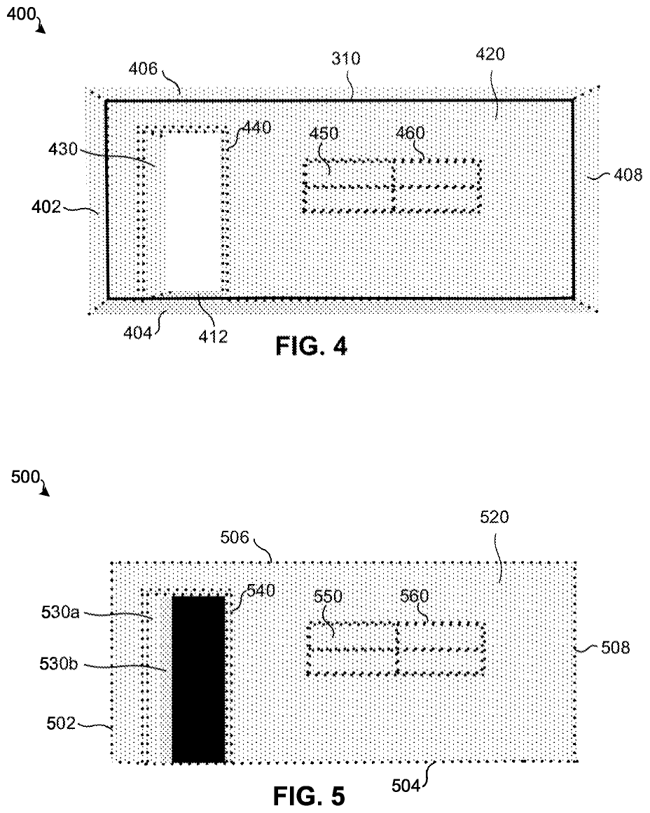

In the process illustrated in FIGS. 2-7, points of the 3D point cloud 200 that are within a threshold distance (e.g., 0.2 meters, 0.4 meters, 0.6 meters, 0.8 meters, 1 meter, 1.2 meters, etc.) of the wall plane 310 are selected. FIG. 4 illustrates a selection of a subset 400 of the 3D point cloud of FIG. 2 within a threshold distance of the wall of FIG. 3. In this example, the distance of each point of the subset 400 is within a threshold distance of a respective closest point on the planar surface 310. A comparison of FIGS. 4 and 5 illustrates that the selected subset of points 400 is fewer than all of the points of the 3D point cloud 200 illustrated in FIG. 4. For example, the subset 400 of points that is selected does not include the points 270 corresponding to desk 170 or the set of points 280 corresponding to the potted plant 180 because these points are not within the threshold distance of the wall plane 310.

Moreover, in some implementations, points on either side of the wall plane 310 are selected. For example, subset 400 of selected points includes points on one side of the wall plane 310 (i.e., the near side) such as a subset of left wall points 402, a subset of floor points 404, a subset of ceiling points 406, a subset of right wall points 408, door frame points 440, and window frame points 460. In addition, the subset 400 of selected points include points on the other side of the wall plane 310 (i.e., the far side) such as the door points 430 and a subset of the floor points 412.

In the process illustrated in FIGS. 2-7, the points of the point cloud 200 that are within the threshold distance of the wall plane 300 that are selected are projected onto a plane, i.e., onto a 2D surface corresponding to the wall plane 310. FIG. 5 illustrates a 2D projection 500 of the subset 400 of selected points of the 3D point cloud 200. In this example, wall points 420 are projected as points 520, the subset of left wall points 402 is projected as points 502 (generally in a line on the left side of the 2D projection 500), the subset of floor points 404 is projected as points 504 (generally in a line on the bottom side of the 2D projection 500), the subset of ceiling points 406 is projected as points 506 (generally in a line on the top side of the 2D projection 500), the subset of right wall points 408 is projected as points 508 (generally in a line on the right side of the 2D projection 500). In this example, the door points 420 are projected as points 530a, 530b, the door frame points 440 are projected as points 540, the window points 450 are projected as points 550, and the window frame points 460 are projected as points 560.

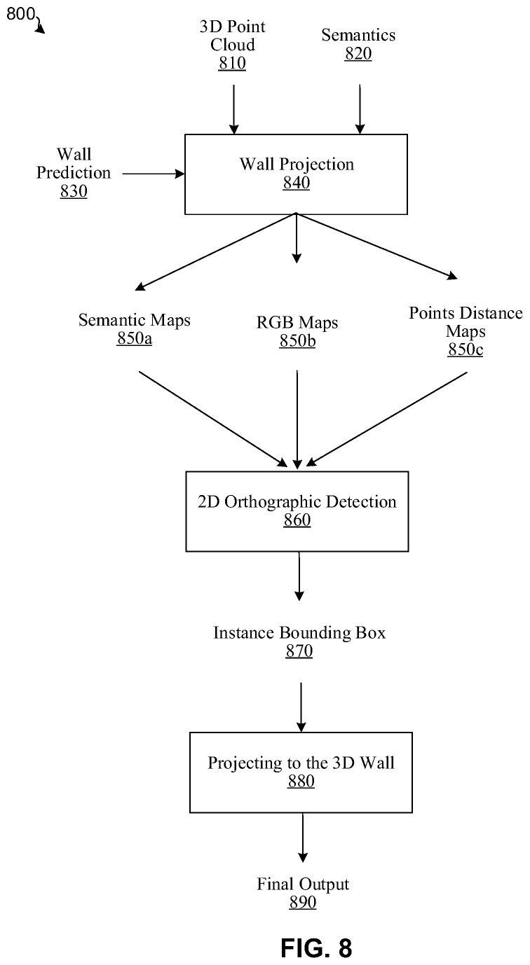

All of these points 502, 504, 506, 508, 520, 530a, 530b, 540, 550, 560 are projected onto a single 2D plane. Characteristics of the points (e.g., color, semantic labels, normal distances of the corresponding 3D points to the wall plane 310, etc.) may be retained in the points of the 2D projection 500. In the example of FIG. 5, the points of the door 430 are varying distances from the wall plane 310. This information may be retained in the 2D projection, for example, by storing information indicative of the distance from the wall plane. This is illustrated graphically in FIG. 5 by the different point style used to represent points 530a versus the points 530b based on points 530a corresponding to a subset of the points 430 that are relatively closer to the wall plane 310 and the points 530b corresponding to a subset of the point 430 that are relatively farther from the wall plane 310. In some implementations, information about the points of the 2D projection is represented using one or more 2D data structures, e.g., maps, matrices, etc., such as using a semantic map, an RGB map, and/or a point distance map. Such maps are described with reference to FIG. 8 below.

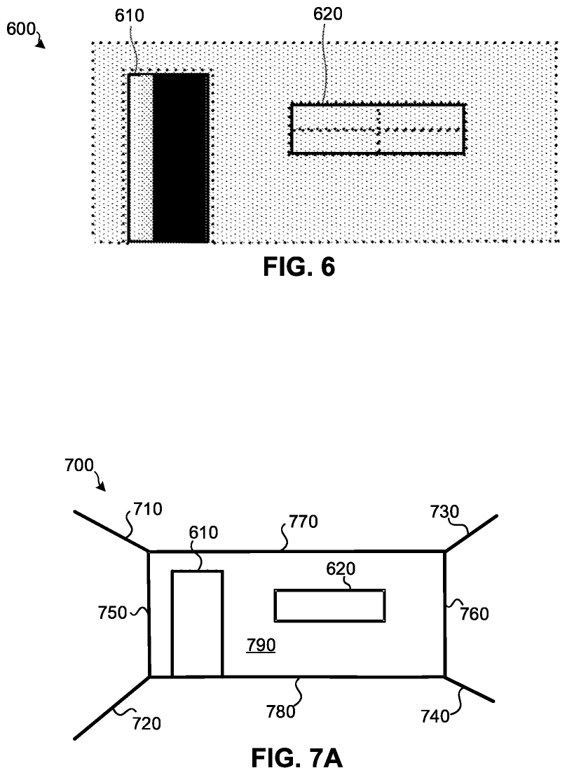

In the process illustrated in FIGS. 2-7, a 2D projection 500 of the subset 400 of the points of the point cloud 200 within the threshold distance of the wall plane 310 is generated as illustrated in FIG. 5. This 3D projection 500 is used to identify a 2D position of a window and a door as illustrated in FIG. 6. FIG. 6 illustrates an identification of a window and a door in the 2D projection of FIG. 5. This may involve evaluating the 2d projection via an algorithm, machine learning model, or other technique configured to identify window and door locations and/or other characteristics using 2D projection data. For example, an object detection deep neural network, i.e., a single stage SSD-like detector, may be trained on 2D projection input to detect axis-aligned bounding boxes of windows, doors, and openings. Such a neural network may be trained, for example, using labelled supervision.

In some implementations, such a technique receives one or more 2D data structures, e.g., maps, matrices, etc., such as using a semantic map, an RGB map, and/or a point distance map and outputs 2D coordinate information or parameters defining the 2D locations of any windows or doors detected within the 2D plane represented by the 2D data structures. In the example of FIG. 6, a door 610 and window 620 are detected. In this example, the detected door 610 has a position and shape corresponding to the location of the door in a closed position/the opening corresponding to the door and the detected window 620 has a position and shape corresponding to a location of the window in closed position. Accordingly, such techniques may detect the position and size of openings corresponding to open doors and/or open windows.

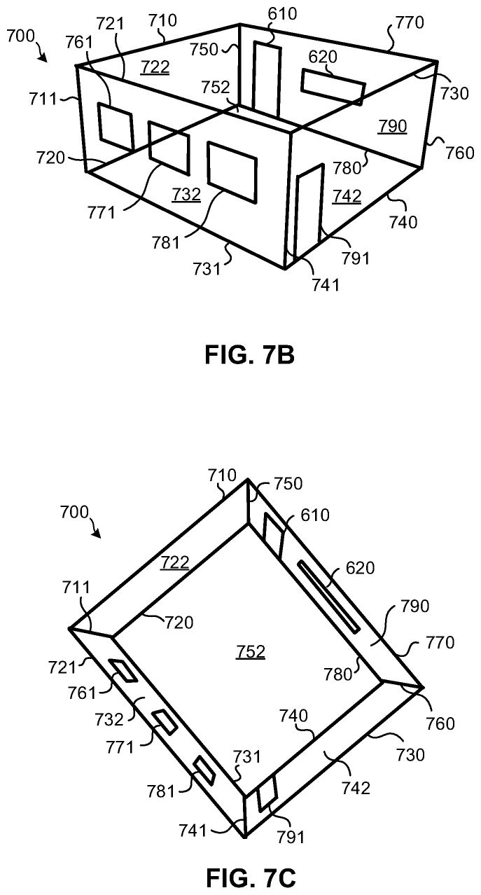

In the process illustrated in FIGS. 2-6, the window 620 and door 610 identified using the 2D projection 500 are used to provide a 3D floor plan 700. FIG. 7A illustrates a view showing a one side of the 3D floor plan 700 representing the physical environment 100 of FIG. 1. The 3D floor plan 700 includes the representations of the window 620 and door 610 of FIG. 6 that were identified based on the 2D projection 500. In addition, the 3D floor plan 700 includes boundaries 710, 720, 730, 740, 750, 760, 770, 780 that define regions (e.g., walls, the floor, etc.) of the 3D floor plan 700 based on corresponding regions of the physical environment 100. For example, boundaries 750, 760, 770, 780 define a wall region corresponding to wall 120. In some implementations, a 3D floor plan 700 is generated by evaluating sensor data and/or a 3D point-based representation (e.g., a 3D point cloud) to identify the 3D positions of boundaries defining the regions of a physical environment 100. Some of those regions, e.g., the wall region defined by boundary lines 750, 760, 770, 780, may correspond to planes that include windows, doors, and openings that are detected using a 2D projection-based detection technique as illustrated in FIGS. 2-7. Given the detection of a window and door on a 2D projection and a 3D position of the 2D projection within a 3D space, the window and door may be positioned within the 3D floor plan 700.

In this example, the window-door detection process determined the 2D positions of window 620 and door 610 on a 2D projection corresponding to wall plane 310. Since wall plane 310 corresponds to the wall region 790 of the 3D floor plan 700, the window 620 and 610 can be positioned within the 3D floor plan 700. In other words, the 3D positions of the door 610 and window 620 in the 3D floor plan 700 are determined based on their 2D positions within the 2D projection 500 and the position of the region 790 of the 3D floor plan 700 that corresponds to the wall plane 310 that corresponds to the 2D projection 500.

In some implementations, a similar process is repeated to detect any windows, doors, and openings in other portions of the physical environment 100 (e.g., on other walls, the ceiling, the floor, etc.) to be represented in the 3D floor plan 700. FIG. 7B and 7C illustrates perspective views of the 3D floor plan 700 of FIG. 7A. The 3D floorplan 700 includes boundaries 710, 720, 730, 740, 750, 760, 770, 780, 711, 721, 731, 741 that define regions (e.g., walls, the floor, the ceiling, etc.). Four boundaries 750, 760, 770, 780 define a first wall region 790. Four boundaries 710, 720, 750, 711 define a second wall region 722. Four boundaries 711, 721, 731, 741 define a third wall region 732. Four boundaries 730, 740, 760, 741 define a fourth wall region 742. Four boundaries 720, 740, 780, 731 define a floor region 752. In this example, the 3D floor plan 700 includes an open ceiling. The 3D floor plan also includes depictions of other windows 761, 771, 781 and a depiction 791 of another door.

The inclusion of windows, doors, and openings in 3D floor plans can provide various benefits. For example, the inclusion of windows may enable potential applications for lighting and energy use estimation. The inclusion of doors may be significant with respect to connecting rooms to one another, for example, in combined 3D floor plans that represent entire buildings.

Some of the techniques disclosed herein convert a 3D window/door detection process into a 2D detection problem on the surface of planes corresponding to walls or other regions of a physical environment. Orthographic detection is well suited for detecting windows, doors, and openings. Such windows, doors, and openings are often rectangular planar objects on a wall or ceiling that are well suited or orthographic detection due to their shapes and planar positioning. Moreover, a rectangular area in a 2D projection with no points is information that can be interpreted. Thus, the 2D projection may actually create or identify information that makes detection of doors, windows, and openings more accurate. Orthographic projection based on a distance threshold may also provide information that may not otherwise be represented as clearly in a 3D point-based representation such as a 3D point cloud. Orthographic projection may also reduce the impact of viewpoints and angles associated with sensor data, for example, by ensuring that rectangular objects are represented as rectangles in the 2D projections. A detection process can be configured to detect such objects without needing to account for the skewed appearance of rectangular objects that might otherwise be required. In some implementations, orthographic projection enables the fusion of 3D semantics (e.g., identifying walls, floors, ceilings, etc.), RGB data, distance data, etc. together at an input layer of the detection process. Orthographic projection may preserve structural information relevant to detecting windows, doors, and openings while reducing the complexity of the information. It may provide information from which clear patterns indicative of doors and windows can be recognized in contrast to the corresponding 3D information from which the relative scarcity of information with respect to 3D space may prevent accurate identification.

FIG. 8 is a flowchart illustrating inputs and outputs in a process 800 for generating a 3D floor plan. In this example, a 3D point cloud 810, semantics 820, and wall predictions 830 are generated from sensor data in a physical environment and input to a wall projection module 840. In alternative implementations these inputs may vary. For example, the wall predictions 830 may be included within the semantics 820.

The wall projection module 840 processes these inputs 810, 820, 830 and produces a 2D projection information 850a-c, for example, by encoding semantics, RGB, and distance information onto a wall plane. The wall plane prediction may predict the position of a wall surface and approximate positions of wall boundaries and/or openings within the wall surface. The 2D projection information includes: semantic maps 850a, RGB maps 850b, and points distance maps 850c. The 2D projection information 850a-c, including semantic maps 850a, RGB maps 850b, and points distance maps 850c, are input to 2D orthographic detection module 860 that detects instances of windows, doors, and/or openings according to the techniques disclosed herein. The 2D orthographic detection module 860 produces instance bounding box information 870 output providing 2D bounding boxes around detected windows, doors, and openings. The instance bounding box information 870 is input to a projecting to the 3D wall module 880 that positions the detected 2D bounding boxes (corresponding to detected windows, doors, and openings) into a 3D coordinate system to produce final output 890 such as a floor plan.

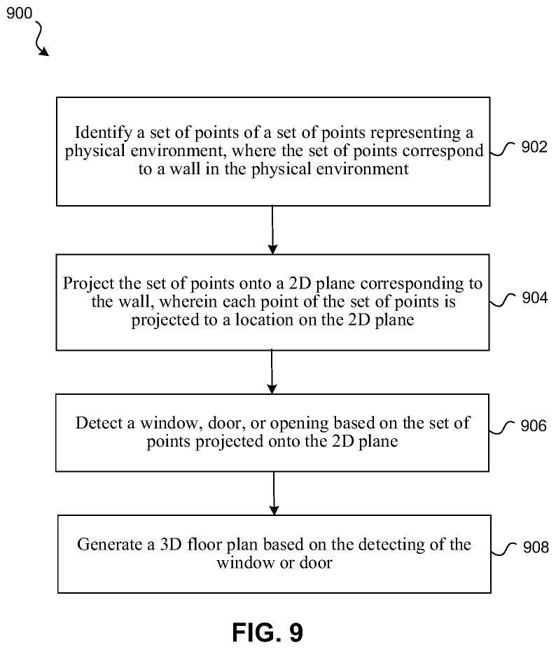

FIG. 9 is a flowchart illustrating a method for generating a 3D floor plan. In some implementations, a device such as electronic device 110 performs method 900. In some implementations, method 900 is performed on a mobile device, desktop, laptop, HMD, or server device. The method 900 is performed by processing logic, including hardware, firmware, software, or a combination thereof. In some implementations, the method 900 is performed on a processor executing code stored in a non-transitory computer-readable medium (e.g., a memory).

At block 902, the method 900 identifies a set of points of a set of points (e.g., of a 3D point cloud or 3D mesh) representing a physical environment, where the set of points correspond to a wall in the physical environment. For example, this may involve identifying a subset of points of a 3D point cloud that are within a threshold distance of a wall plane as illustrated in FIG. 4.

At block 904, the method 900 projects the set of points onto a 2D plane corresponding to the wall, where each point of the set of points is projected to a location on the 2D plane. The 2D plane corresponding to the wall may be predicted using a process that evaluates the set of points to predict the position of a wall surface and approximate positions of wall boundaries and/or openings within the wall surface. The points of the set of points may be projected onto the 2D plane by orthographic projection. For example, a subset set of points of a 3D point cloud may be orthographically projected onto a plane as illustrated in FIG. 5. In some implementations, each point may additionally be associated with information including, but not limited to, semantics, color/RGB info, and/or normalized distance info of the points from the wall in the 3D point cloud. In some implementations, the projecting involves providing 2D data sets such as (a) a semantic map (b) an RGB map and (c) a point distance map, as illustrated in FIG. 8. The point distance map may provide normalized distance information, where the set of points and the 2D plane are associated with positions with a common 3D coordinate system and the normalized distance information corresponds to distances of the points of the set of points the 2D plane in the common 3D coordinate system.

At block 906, the method 900 detects a window, door, or opening based on the set of points projected onto the 2D plane. For example, this may involve a 2D orthographic detection process as illustrated in FIG. 6. The detecting may involve predicting whether the door is open, closed, etc. In some implementations, detecting the window, door, or opening is based on the set of points is based on the 2D semantic map, the 2D color map, and the 2D points distance map, as illustrated in FIG. 8. In some implementations, detecting the window, door, or opening comprises 2D orthographic detection of a bounding box corresponding to a boundary of the window, door, or opening in the 2D plane. In some implementations, openings in the wall plane may have been predicted/approximated as part of the 2D plane prediction process. In such implementations, the detection of openings (and doors and windows) in block 906 may involve assessing the points projected onto the 2D plane and/or assessing the prediction/approximation of openings from the 2D plane prediction process.

At block 908, the method 900 generates a 3D floor plan based on the detecting of the window, door, or opening. Other portions of the 3D floor plan such as a representation of the wall (and other walls) may be generated based on the 3D point cloud and the window, door, or opening may be positioned based on a known spatial relationship of the wall plane used to detect the window, door, or opening and the 3D point cloud. FIG. 7 illustrates a 3D floor plan generated based on the detection of a window and a door. In some implementations, the set of points and the 2D plane are associated with positions with a common 3D coordinate system and generating the 3D floor plan involves generating a representation of the wall based on the set of points and positioning a representation of the window, door, or opening based in the 3D floor plan based on the common 3D coordinate system. In some implementations, generating the 3D floor plan comprises generating representations of window, door, or opening on representations of multiple walls of the physical environment.

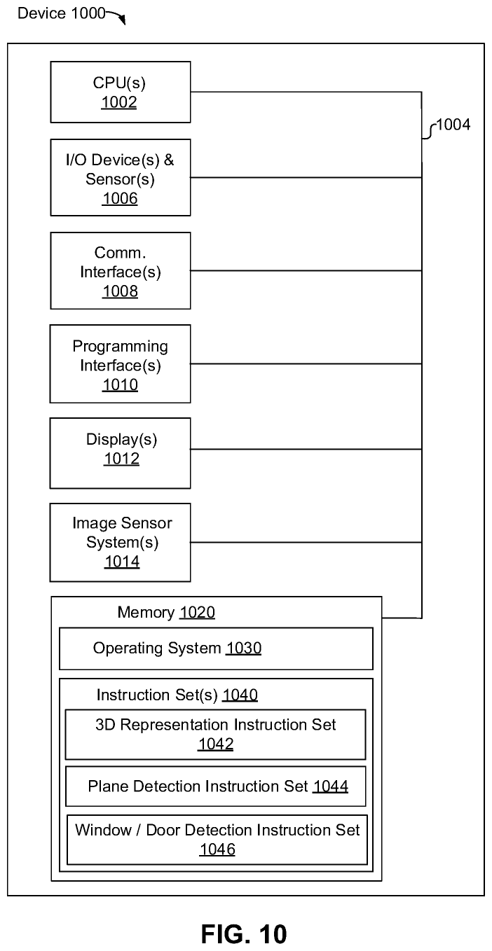

FIG. 10 is a block diagram of electronic device 1000. Device 1000 illustrates an exemplary device configuration for electronic device 110. While certain specific features are illustrated, those skilled in the art will appreciate from the present disclosure that various other features have not been illustrated for the sake of brevity, and so as not to obscure more pertinent aspects of the implementations disclosed herein. To that end, as a non-limiting example, in some implementations the device 1000 includes one or more processing units 1002 (e.g., microprocessors, ASICs, FPGAs, GPUs, CPUs, processing cores, and/or the like), one or more input/output (I/O) devices and sensors 1006, one or more communication interfaces 1008 (e.g., USB, FIREWIRE, THUNDERBOLT, IEEE 802.3x, IEEE 802.11x, IEEE 802.16x, GSM, CDMA, TDMA, GPS, IR, BLUETOOTH, ZIGBEE, SPI, I2C, and/or the like type interface), one or more programming (e.g., I/O) interfaces 1010, one or more output device(s) 1012, one or more interior and/or exterior facing image sensor systems 1014, a memory 1020, and one or more communication buses 1004 for interconnecting these and various other components.

In some implementations, the one or more communication buses 1004 include circuitry that interconnects and controls communications between system components. In some implementations, the one or more I/O devices and sensors 1006 include at least one of an inertial measurement unit (IMU), an accelerometer, a magnetometer, a gyroscope, a thermometer, one or more physiological sensors (e.g., blood pressure monitor, heart rate monitor, blood oxygen sensor, blood glucose sensor, etc.), one or more microphones, one or more speakers, a haptics engine, one or more depth sensors (e.g., a structured light, a time-of-flight, or the like), and/or the like.

In some implementations, the one or more output device(s) 1012 include one or more displays configured to present a view of a 3D environment to the user. In some implementations, the one or more displays 1012 correspond to holographic, digital light processing (DLP), liquid-crystal display (LCD), liquid-crystal on silicon (LCoS), organic light-emitting field-effect transitory (OLET), organic light-emitting diode (OLED), surface-conduction electron-emitter display (SED), field-emission display (FED), quantum-dot light-emitting diode (QD-LED), micro-electromechanical system (MEMS), and/or the like display types. In some implementations, the one or more displays correspond to diffractive, reflective, polarized, holographic, etc. waveguide displays. In one example, the device 1000 includes a single display. In another example, the device 1000 includes a display for each eye of the user.

In some implementations, the one or more output device(s) 1012 include one or more audio producing devices. In some implementations, the one or more output device(s) 1012 include one or more speakers, surround sound speakers, speaker-arrays, or headphones that are used to produce spatialized sound, e.g., 3D audio effects. Such devices may virtually place sound sources in a 3D environment, including behind, above, or below one or more listeners. Generating spatialized sound may involve transforming sound waves (e.g., using head-related transfer function (HRTF), reverberation, or cancellation techniques) to mimic natural soundwaves (including reflections from walls and floors), which emanate from one or more points in a 3D environment. Spatialized sound may trick the listener's brain into interpreting sounds as if the sounds occurred at the point(s) in the 3D environment (e.g., from one or more particular sound sources) even though the actual sounds may be produced by speakers in other locations. The one or more output device(s) 1012 may additionally or alternatively be configured to generate haptics.

In some implementations, the one or more image sensor systems 1014 are configured to obtain image data that corresponds to at least a portion of a physical environment. For example, the one or more image sensor systems 1014 may include one or more RGB cameras (e.g., with a complimentary metal-oxide-semiconductor (CMOS) image sensor or a charge-coupled device (CCD) image sensor), monochrome cameras, IR cameras, depth cameras, event-based cameras, and/or the like. In various implementations, the one or more image sensor systems 1014 further include illumination sources that emit light, such as a flash. In various implementations, the one or more image sensor systems 1014 further include an on-camera image signal processor (ISP) configured to execute a plurality of processing operations on the image data.

The memory 1020 includes high-speed random-access memory, such as DRAM, SRAM, DDR RAM, or other random-access solid-state memory devices. In some implementations, the memory 1020 includes non-volatile memory, such as one or more magnetic disk storage devices, optical disk storage devices, flash memory devices, or other non-volatile solid-state storage devices. The memory 1020 optionally includes one or more storage devices remotely located from the one or more processing units 1002. The memory 1020 comprises a non-transitory computer readable storage medium.

In some implementations, the memory 1020 or the non-transitory computer readable storage medium of the memory 1020 stores an optional operating system 1030 and one or more instruction set(s) 1040. The operating system 1030 includes procedures for handling various basic system services and for performing hardware dependent tasks. In some implementations, the instruction set(s) 1040 include executable software defined by binary information stored in the form of electrical charge. In some implementations, the instruction set(s) 1040 are software that is executable by the one or more processing units 1002 to carry out one or more of the techniques described herein.

The instruction set(s) 1040 include a 3D representation instruction set 1042 configured to, upon execution, obtain sensor data, provide views/representations, select sets of sensor data, and/or generate 3D point clouds, 3D meshes, 3D floor plans, and/or other 3D representations of physical environments as described herein. The instruction set(s) 1040 further include a plane detection instruction set 1044 configured to detect planes such as walls, ceilings, floors, and the like in physical environments and/or corresponding 3D point-based representations as described herein. The instruction set(s) 1040 further include a window/door/opening detection instruction set configured to detect windows, doors, and openings in physical environments and/or corresponding 3D point-based representations. The instruction set(s) 1040 may be embodied as a single software executable or multiple software executables.

Although the instruction set(s) 1040 are shown as residing on a single device, it should be understood that in other implementations, any combination of the elements may be located in separate computing devices. Moreover, the figure is intended more as functional description of the various features which are present in a particular implementation as opposed to a structural schematic of the implementations described herein. As recognized by those of ordinary skill in the art, items shown separately could be combined and some items could be separated. The actual number of instructions sets and how features are allocated among them may vary from one implementation to another and may depend in part on the particular combination of hardware, software, and/or firmware chosen for a particular implementation.

It will be appreciated that the implementations described above are cited by way of example, and that the present invention is not limited to what has been particularly shown and described hereinabove. Rather, the scope includes both combinations and sub combinations of the various features described hereinabove, as well as variations and modifications thereof which would occur to persons skilled in the art upon reading the foregoing description and which are not disclosed in the prior art.

As described above, one aspect of the present technology is the gathering and use of sensor data that may include user data to improve a user's experience of an electronic device. The present disclosure contemplates that in some instances, this gathered data may include personal information data that uniquely identifies a specific person or can be used to identify interests, traits, or tendencies of a specific person. Such personal information data can include movement data, physiological data, demographic data, location-based data, telephone numbers, email addresses, home addresses, device characteristics of personal devices, or any other personal information.

The present disclosure recognizes that the use of such personal information data, in the present technology, can be used to the benefit of users. For example, the personal information data can be used to improve the content viewing experience. Accordingly, use of such personal information data may enable calculated control of the electronic device. Further, other uses for personal information data that benefit the user are also contemplated by the present disclosure.

The present disclosure further contemplates that the entities responsible for the collection, analysis, disclosure, transfer, storage, or other use of such personal information and/or physiological data will comply with well-established privacy policies and/or privacy practices. In particular, such entities should implement and consistently use privacy policies and practices that are generally recognized as meeting or exceeding industry or governmental requirements for maintaining personal information data private and secure. For example, personal information from users should be collected for legitimate and reasonable uses of the entity and not shared or sold outside of those legitimate uses. Further, such collection should occur only after receiving the informed consent of the users. Additionally, such entities would take any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices.

Despite the foregoing, the present disclosure also contemplates implementations in which users selectively block the use of, or access to, personal information data. That is, the present disclosure contemplates that hardware or software elements can be provided to prevent or block access to such personal information data. For example, in the case of user-tailored content delivery services, the present technology can be configured to allow users to select to “opt in” or “opt out” of participation in the collection of personal information data during registration for services. In another example, users can select not to provide personal information data for targeted content delivery services. In yet another example, users can select to not provide personal information, but permit the transfer of anonymous information for the purpose of improving the functioning of the device.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences or settings based on non-personal information data or a bare minimum amount of personal information, such as the content being requested by the device associated with a user, other non-personal information available to the content delivery services, or publicly available information.

In some embodiments, data is stored using a public/private key system that only allows the owner of the data to decrypt the stored data. In some other implementations, the data may be stored anonymously (e.g., without identifying and/or personal information about the user, such as a legal name, username, time and location data, or the like). In this way, other users, hackers, or third parties cannot determine the identity of the user associated with the stored data. In some implementations, a user may access their stored data from a user device that is different than the one used to upload the stored data. In these instances, the user may be required to provide login credentials to access their stored data.

Numerous specific details are set forth herein to provide a thorough understanding of the claimed subject matter. However, those skilled in the art will understand that the claimed subject matter may be practiced without these specific details. In other instances, methods apparatuses, or systems that would be known by one of ordinary skill have not been described in detail so as not to obscure claimed subject matter.

Unless specifically stated otherwise, it is appreciated that throughout this specification discussions utilizing the terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provides a result conditioned on one or more inputs. Suitable computing devices include multipurpose microprocessor-based computer systems accessing stored software that programs or configures the computing system from a general-purpose computing apparatus to a specialized computing apparatus implementing one or more implementations of the present subject matter. Any suitable programming, scripting, or other type of language or combinations of languages may be used to implement the teachings contained herein in software to be used in programming or configuring a computing device.

Implementations of the methods disclosed herein may be performed in the operation of such computing devices. The order of the blocks presented in the examples above can be varied for example, blocks can be re-ordered, combined, and/or broken into sub-blocks. Certain blocks or processes can be performed in parallel.

The use of “adapted to” or “configured to” herein is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or value beyond those recited. Headings, lists, and numbering included herein are for ease of explanation only and are not meant to be limiting.

It will also be understood that, although the terms “first,” “second,” etc. may be used herein to describe various elements, these elements should not be limited by these terms. These terms are only used to distinguish one element from another. For example, a first node could be termed a second node, and, similarly, a second node could be termed a first node, which changing the meaning of the description, so long as all occurrences of the “first node” are renamed consistently and all occurrences of the “second node” are renamed consistently. The first node and the second node are both nodes, but they are not the same node.

The terminology used herein is for the purpose of describing particular implementations only and is not intended to be limiting of the claims. As used in the description of the implementations and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description and summary of the invention are to be understood as being in every respect illustrative and exemplary, but not restrictive, and the scope of the invention disclosed herein is not to be determined only from the detailed description of illustrative implementations but according to the full breadth permitted by patent laws. It is to be understood that the implementations shown and described herein are only illustrative of the principles of the present invention and that various modification may be implemented by those skilled in the art without departing from the scope and spirit of the invention.

What is claimed is:

1. A method comprising:
at a device having a processor:
identifying a set of points representing a three-dimensional (3D) appearance of a physical environment, wherein the set of points correspond to a wall in the physical environment;
projecting the set of points onto a two-dimensional (2D) plane corresponding to the wall, wherein each point of the set of points is projected to a location on the 2D plane;
detecting a window, door, or opening based on the set of points projected onto the 2D plane; and
generating a 3D floor plan based on the detecting of the window, door, or opening.

2. The method of claim 1, wherein identifying the set of points that correspond to the wall comprises identifying points of the set of points within a threshold distance of the wall.

3. The method of claim 1, wherein projecting the set of points onto the 2D plane comprises orthographic projection.

4. The method of claim 1, wherein points of the set of points are associated with semantic labels and the projecting comprises a generating a 2D semantic map based on the projecting.

5. The method of claim 1, wherein points of the set points are associated with color information and the projecting comprises a generating a 2D color map based on the projecting.

6. The method of claim 1, wherein points of the set points are associated with normalized distance information, wherein the set of points and the 2D plane are associated with positions with a common 3D coordinate system and the normalized distance information corresponds to distances of the points of the set of points the 2D plane in the common 3D coordinate system.

7. The method of claim 1, wherein:
projecting the set of points comprises generating a 2D semantic map, a 2D color map, and a 2D points distance map; and
detecting the window, door, or opening is based on the set of points is based on the 2D semantic map, the 2D color map, and the 2D points distance map.

8. The method of claim 1, wherein detecting the window, door, or opening comprises 2D orthographic detection of a bounding box corresponding to a boundary of the window, door, or opening in the 2D plane.

9. The method of claim 1, wherein detecting the window, door, or opening comprises detecting whether the window or door is open or closed.

10. The method of claim 1, wherein:
the set of points and the 2D plane are associated with positions with a common 3D coordinate system; and
generating the 3D floor plan comprises generating a representation of the wall based on the set of points and positioning a representation of the window, door, or opening based in the 3D floor plan based on the common 3D coordinate system.

11. The method of claim 1, wherein generating the 3D floor plan comprises generating representations of window, door, or opening on representations of multiple walls of the physical environment.

12. A system comprising:
a non-transitory computer-readable storage medium; and
one or more processors coupled to the non-transitory computer-readable storage medium, wherein the non-transitory computer-readable storage medium comprises program instructions that, when executed on the one or more processors, cause the system to perform operations comprising:
identifying a set of points of a three-dimensional (3D) model representing a physical environment, wherein the set of points correspond to a wall in the physical environment;
projecting the set of points onto a two-dimensional (2D) plane corresponding to the wall, wherein each point of the set of points is projected to a location on the 2D plane;
detecting a window, door, or opening based on the set of points projected onto the 2D plane; and
generating a 3D floor plan based on the detecting of the window, door, or opening.

13. The device of claim 12, wherein identifying the set of points that correspond to the wall comprises identifying points of the set of points within a threshold distance of the wall.

14. The device of claim 12, wherein projecting the set of points onto the 2D plane comprises orthographic projection.

15. The device of claim 12, wherein points of the set of points are associated with semantic labels and color information and the projecting comprises a generating a 2D semantic map and a 2d color map based on the projecting.

16. The device of claim 12, wherein points of the set points are associated with normalized distance information, wherein the set of points and the 2D plane are associated with positions with a common 3D coordinate system and the normalized distance information corresponds to distances of the points of the set of points the 2D plane in the common 3D coordinate system.

17. The device of claim 12, wherein:
projecting the set of points comprises generating a 2D semantic map, a 2D color map, and a 2D points distance map; and
detecting the window, door, or opening is based on the set of points is based on the 2D semantic map, the 2D color map, and the 2D points distance map.

18. The device of claim 12, wherein detecting the window, door, or opening comprises 2D orthographic detection of a bounding box corresponding to a boundary of the window, door, or opening in the 2D plane.

19. The device of claim 12, wherein detecting the window, door, or opening comprises detecting whether the window, door, or opening is open or closed.

20. A non-transitory computer-readable storage medium storing program instructions executable via one or more processors to perform operations comprising:
identifying a set of points of a three-dimensional (3D) model representing a physical environment, wherein the set of points correspond to a wall in the physical environment;
projecting the set of points onto a two-dimensional (2D) plane corresponding to the wall, wherein each point of the set of points is projected to a location on the 2D plane;
detecting a window, door, or opening based on the set of points projected onto the 2D plane; and
generating a 3D floor plan based on the detecting of the window, door, or opening.
